(19) United States
(12) Patent Application Publication
(10) Pub. No.: US 2017/0175255 A1
(43) Pub. Date: Jun. 22, 2017

(54) METHOD OF SPUTTER DEPOSITION OF A FILM ON AN ESSENTIALLY PLANE EXTENDED SURFACE OF A SUBSTRATE

(71) Applicant: EVATEC ADVANCED TECHNOLOGIES AG, Balzers (LI)

(72) Inventors: Oliver RATTUNDE, Werdenberg (CH); Hans HIRSCHER, Bad Ragaz (CH)

(73) Assignee: EVATEC ADVANCED TECHNOLOGIES AG, Balzers (LI)

(21) Appl. No.: 15/118,416

(22) PCT Filed: Feb. 13, 2015
(86) PCT No.: PCT/EP2015/053072

§ 371 Date: Aug. 11, 2016

Related U.S. Application Data
(60) Provisional application No. 61/942,232, filed on Feb. 20, 2014.

(51) Int. Cl. C23C 14/54; C23C 14/34; C23C 14/04; H01J 37/34; H01J 37/20

(52) U.S. Cl. CPC C23C 14/542; H01J 37/347; H01J 37/20; C23C 14/046; C23C 14/3492

(57) ABSTRACT

A film is sputter-deposited on an essentially plane, extended surface of a substrate which has recesses therein, namely at least one of grooves, of holes, of bores, of vias, of trenches. So as to establish on one hand a homogeneous thickness distribution of the film along the addressed surface of the substrate and, on the other hand, a thick film deposition within the recesses, sputter deposition is performed first at a large distance between a sputter surface of a target and the addressed surface of the substrate and then at a reduced distance between the addressed surfaces.

The invention relates to sputter deposition of a thin film on a 3D structured, essentially plane and extended surface of a substrate having recesses in the extended surface, namely at least one of grooves, of holes, of bores, of vias, of trenches as e.g. used in semiconductor applications.

Thin film deposition by sputtering on essentially plane, extended surfaces having recesses as addressed suffers from reduced film thickness in deeper parts of the recesses (also called “grooves” from now on) due to shadowing from neighboring, elevated parts of the grooves. This shadowing effect depends on the specific groove feature (exact form and aspect ratio) as well as on the overall thickness of the deposited material—thicker films leading to more severe shadowing effects.

It is well known in the industry that besides temperature and material specific effects like surface diffusion and other reflow processes, the angular distribution of the atoms impinging on the surface to be coated is a key parameter of influencing shadowing and therefore of the desired groove filling on 3D structured surfaces. In sputtering applications the angular distribution of the impinging atoms onto the substrate surface is mainly a function of 1) the specific erosion pattern of the sputter target, and 2) the geometry of the sputtering apparatus, i.e. the dimension of sputter target and of the substrate respectively, the distance between target and substrate surface (“TSD”—Target Substrate Distance), and the angle between target and substrate surface.

If all input parameters in 1) and 2) are known it is possible to simulate the angular distribution of the impinging atoms as well as the resulting topography of the deposited film, e.g. by applying the so-called string algorithm originally developed by Bader et. al. (J. Vac. Sci. and Technol. A, Vol 3, (1985), p2167-2171).

It is on object of the present invention to provide a method of sputter coating substrates of the addressed type so that on one hand the sputter deposited layer along the essentially plane, extended surface of the substrate has an improved homogeneity of thickness distribution along the surface and, on the other hand, the bottom area of the recesses becomes covered by the sputter deposited layer having an increased thickness.

This is achieved by a method of sputter depositing of a film on an essentially plane, extended surface of a substrate, whereby the surface has recesses, namely at least one of grooves, of holes, of bores, of vias, of trenches. The method comprises:

Positioning the addressed surface parallel, distant from and opposite an essentially plane sputter surface of a target of a sputtering source,

first sputter coating the addressed surface of the substrate by the sputtering source thereby establishing a first distance between the addressed sputter surface of the target and the addressed surface of the substrate, and subsequently second sputter coating the addressed surface of the substrate by the sputtering source thereby establishing a second distance between the addressed sputter surface of the target and the addressed surface of the substrate and selecting the first distance larger than the second distance.

In one embodiment of the method according to the invention which may be combined with any of the embodiments subsequently addressed unless in contradiction, the second distance is selected to be substantially half the first distance.

In one embodiment of the method according to the invention which may be combined with any of the embodiments already addressed and to be subsequently addressed unless in contradiction, sputter coating between said first and second sputter coatings is interrupted. This means that the plasma discharge of the sputter source is extinguished or at least reduced in its intensity so as to result in a practically neglectable sputtering effect.

In one embodiment of the method according to the invention which may be combined with any of the embodiments already addressed and to be subsequently addressed unless in contradiction, there is ongoingly performed sputter coating during changing from the first to the second distance.

The invention is further directed to a method of manufacturing a substrate having an essentially plane, extended surface which has recesses, namely at least one of grooves, of holes, of bores, of vias, of trenches and whereat the addressed surface including the addressed recesses is covered by a film. The addressed film is thereby deposited by the method of sputter deposition as was addressed above or according to one or more than one of the addressed embodiments thereof.

The invention and the findings whereupon the invention is based shall now be further explained and exemplified with the help of figures. The figures show:

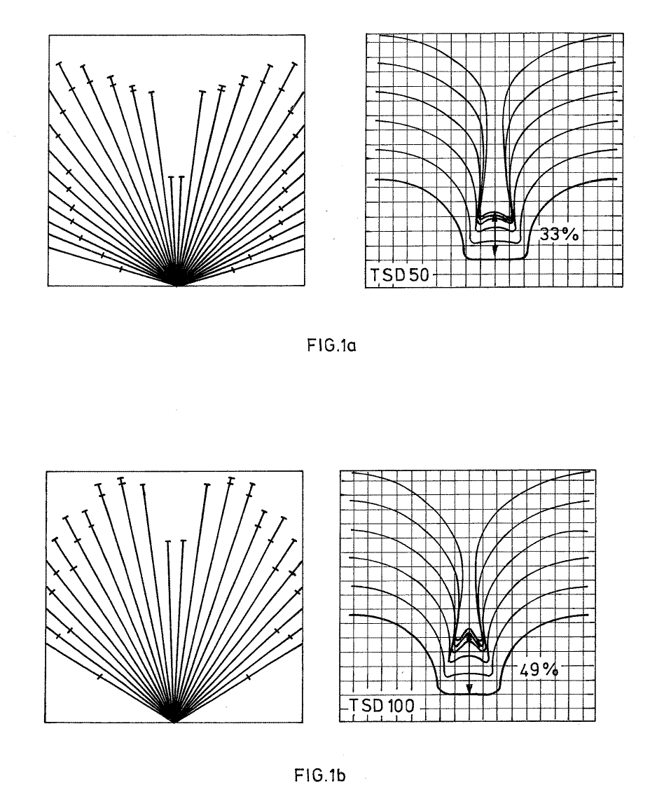

FIGS. 1a and 1b: Calculated angular distribution of the sputtered atom at the substrate (left) and simulated deposition (right) for two different target substrate distances (TSD) a) 50 mm, and b) 100 mm.

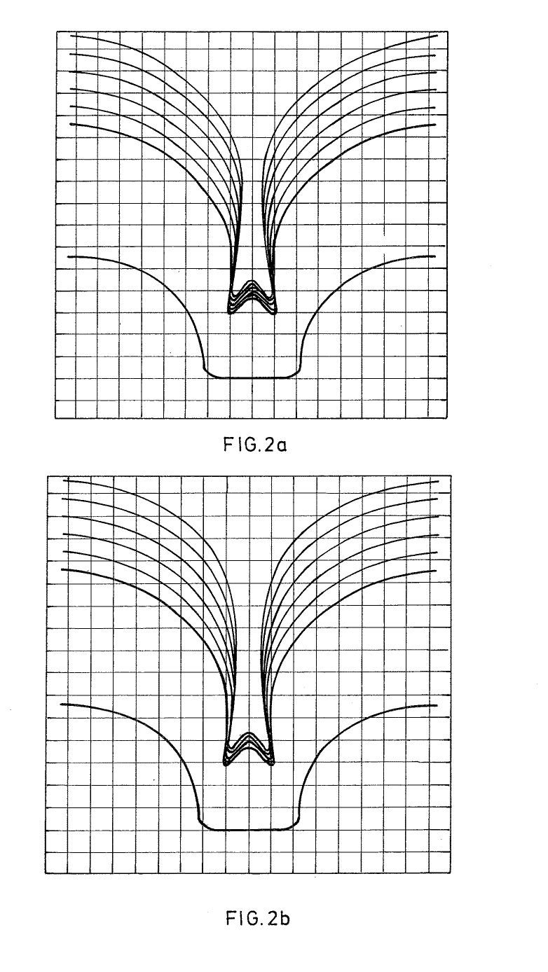

FIGS. 2a and 2b: The simulated deposition of a 2 μm thick film on top of a 3 μm thick film deposited at TSD100 whereas the last 2 μm are deposited at a) TSD100 (α=100%) and b) TSD50 (α=60%).

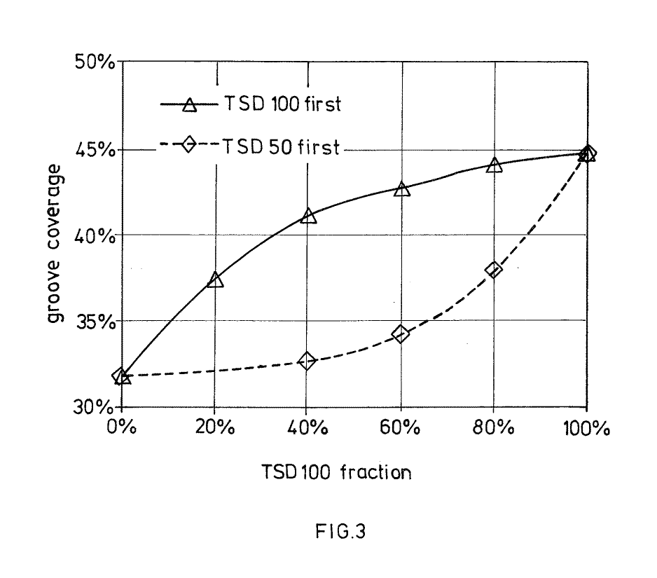

FIG. 3: The simulated groove coverage for the two-step process comprising a deposition step at large TSD (TSD100) and at small TSD (TSD50) respectively for a total film thickness of 5 μm.

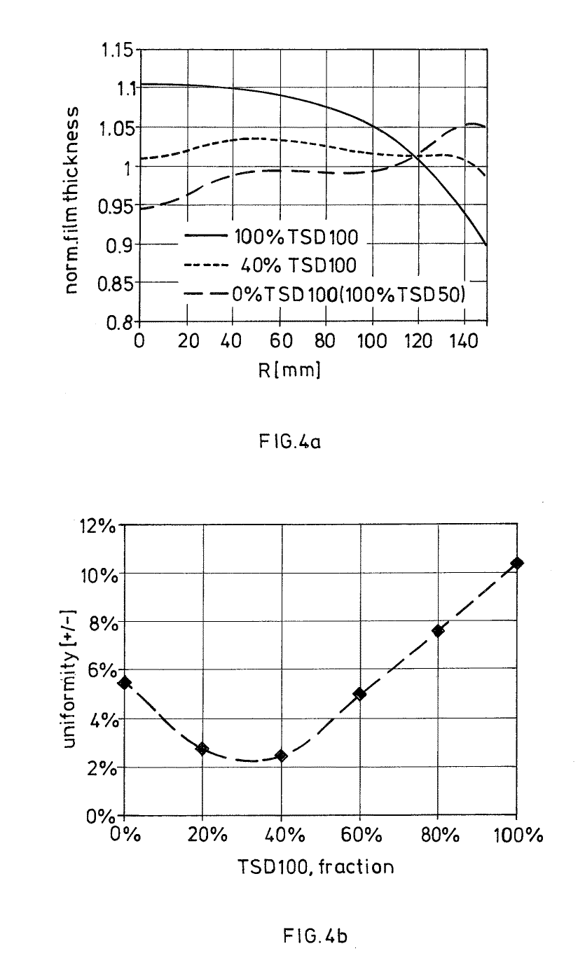

FIGS. 4a and 4b: The calculated radial film thickness on a 300 mm wafer (a) together with the resulting film thickness uniformity (b) for a two-step process at TSD100/TSD50.

FIG. 1a) and b) show results of a simulation as addressed above in two dimensions for a planar arrangement of target and substrate for different TSDs. This and all further addressed coverage simulations as well as film thickness uniformity calculations are based on a state of the art sputtering deposition tool for 300 mm wafers using a sputter target with diameter of 400 mm. It may clearly be seen, that a low TSD (FIG. 1a) results in a reduced groove filling as due to a more oblique angle of incidence of atoms upon the surface of the substrate and thus an increased shadowing effect.

The arrows in FIG. 1a and FIG. 1b indicate the groove filling relative to the film thickness at the topmost two-dimensionally extended surface of the substrate.

On the other hand, the film thickness uniformity on the substrate for a given target size and geometry usually deteriorates (shows a fall-off towards the edge of the substrate) when increasing the TSD. This, considered per se, can be compensated by changing the target erosion pattern towards increased erosion at large target radii, but this automatically leads to an unfavorable, more oblique angle of incidence in the center of the substrate—thus leading to a reduced groove filling in this position.

Generally speaking good film thickness uniformity is contrary to good groove filling.

Another important aspect are costs: Actual target size for a given substrate diameter (e.g. 300 mm wafer) always results from a compromise between good process performance (e.g. large target diameter for good film thickness uniformity—especially at large TSD) and cost issues (transfer factor, target costs—both being lower for smaller target diameters). Therefore target size needs also to be taken into account when trying to solve the dilemma of good film thickness uniformity as well as of good groove filling.

A. Combined improvement of layer thickness homogeneity and of groove filling may be attempted by ionized sputtering which requires Rf bias of the substrate, large targets and large TSD and is thus expensive.

The present invention is, based on the findings out of the FIGS. 1a and 1b, a thin film deposition process by sputtering which consists of two consecutive steps whereas the first step comprises deposition of a fraction α of the desired film thickness at large TSD for optimized groove coverage, and the second step comprises deposition of a fraction 1-α of the desired film thickness at small TSD for compensating the film thickness un-uniformity of the first step.

Such two-step process may be named “Zoom-Process”.

Computer simulations as described above have revealed that especially for larger film thicknesses (being of the same order of magnitude as the dimensions of the substrate pattern) only the beginning of the film deposition benefits strongly from favorable deposition conditions at large TDS (narrower angular distribution of the impinging atoms) whereas at the end of the deposition process the contribution of the additional film deposition to the groove coverage is small anyhow—thus deposition at small or large TSD results only in a minor difference in overall groove coverage.

Thus, a reduction of the fraction a of the overall film thickness deposited at large TSD (e.g. from 100% to 60-80%) results in only slightly reduced groove filling if, and only if, the large TSD step is applied first.

In FIGS. 2a and 2b there is shown the simulated deposition of a 2 μm thick film on top of a 3 μm thick film deposited at TSD100 whereas the last 2 μm are deposited at a) TSD100 (α=100%) and b) TSD50 (α=60%).

On the other side, when looking at film thickness uniformity, a two-step process can significantly improve the film thickness uniformity. The resulting film thickness distribution is a simple superposition of the two steps and therefore the resulting film thickness uniformity is reached irrespectively whether the small TSD or the large TSD step is applied first.

The film thickness uniformity as addressed throughout the description and claims refers to the film thickness distribution along the complete substrate e.g. and in this example a 300 mm wafer, which is significantly larger than the dimension of the recesses of the substrate pattern.

As a conclusion, the disclosed two-step process (using the large TSD process first) results in a superior deposition process which solves the dilemma of optimizing both, groove filling and film thickness uniformity at the same time. In addition, since good film thickness uniformity is achieved by operating the process at small TSD, the target diameter can also be kept quite small which has significant cost advantages.

Based on these theoretical considerations a process was established on a cluster-like sputter deposition tool with the ability to change the TSD in the very same process module. This change of TSD can be performed by altering the chuck height either during processing (i.e. the plasma stays ON during chuck movement) or by pausing the deposition process during the chuck movement. Both ways of in situ chuck height adjustments during a process sequence are also part of the disclosure of this invention.

FIG. 3 shows the simulated groove coverage for a two-step process comprising the deposition step at large TSD (TSD100) first or at small TSD (TSD50) first, for a total film thickness of 5 μm.

FIGS. 4a and 4b show the calculated radial film thickness on a 300 mm wafer (a) and the resulting film thickness uniformity (b) for a two-step process at TSD100 first and then at TSD50.

1. A method of sputter depositing of a film on an essentially plane extended surface of a substrate, said surface having recesses namely at least one of grooves, of holes, of bores, of vias, of trenches comprising:
Positioning said surface of said substrate parallel, distant from and opposite an essentially plane sputter surface of a target of a sputtering source,
first sputter coating said surface of said substrate by the sputtering source thereby establishing a first distance between said sputter surface of said target and said surface of said substrate, and subsequently
second sputter coating said surface of said substrate by said sputtering source thereby establishing a second distance between said sputter surface of said target and said surface of said substrate and selecting the first distance larger than the second distance.

2. The method of claim 1 comprising selecting said second distance substantially half said first distance.

3. The method of claim 1 comprising interrupting sputter coating between said first and second sputter coatings.

4. The method of one of claim 1 comprising ongoingly sputter coating during changing from said first to said second distance.

5. A method of manufacturing a substrate having an essentially plane extended surface which has recesses namely at least one of grooves, of holes, of bores, of vias, of trenches, and whereat said surface including said recesses is covered by a film, said film being deposited by the method of claim 1.
